(19) United States
(12) Patent Application Publication
(10) Pub. No.: US 2020/0209428 A1
(43) Pub. Date: Jul. 2, 2020

(54) REAL-TIME RESERVOIR SURVEILLANCE-MANAGEMENT SYSTEM

(71) Applicant: ExxonMobil Upstream Research Company, Spring, TX (US)

(72) Inventors: Amr S. EL-BAKRY, Houston, TX (US); Kushal S. KEDIA, Houston, TX (US); Steven D. VANDE LUNE, Spring, TX (US); Tom C. RYAN, Houston, TX (US)

(21) Appl. No.: 16/702,837

(22) Filed: Dec. 4, 2019

Related U.S. Application Data
(60) Provisional application No. 62/786,769, filed on Dec. 31, 2018.

(51) Int. Cl. G01V 99/00; G06F 30/20; E21B 49/00; E21B 47/10; E21B 47/06

(52) U.S. Cl. CPC G01V 99/005; G06F 30/20; E21B 49/00; E21B 43/16; E21B 47/06; E21B 47/065; E21B 47/1015

(57) ABSTRACT

A system and method of monitoring a field includes obtaining field data for an injector well coupled to a reservoir; obtaining a model comprising representations of at least one of the wells and/or the reservoir; updating the model with the field data for the injector well; and assessing a status (e.g., injector health assessment) of the injector well based on the field data and the model. A system and method of reservoir management includes solving an optimization problem based on unconstrained injection allocation target rates for one or more injector wells and weightings dependent upon relative travel times between injector-producer well pairs, each injector-producer well pairs comprising one of the injector wells; determining injection allocation targets based on the solution of the optimization problem; designing a production optimization strategy based on the injection allocation targets.

### CROSS REFERENCE TO RELATED APPLICATIONS

This application claims the priority benefit of United States Provisional Patent Application No. 62/786,769, filed Dec. 31, 2018, entitled REAL-TIME RESERVOIR surveillance—MANAGEMENT SYSTEM.

### FIELD

This disclosure relates generally to the field of hydrocarbon recovery and/or reservoir management operations to enable production of subsurface hydrocarbons. Specifically, exemplary embodiments relate to methods and apparatus for monitoring, managing, initiating, and/or regulating fluid injection for a reservoir. Additionally, exemplary embodiments relate to methods and apparatus for real-time reservoir management operations.

### BACKGROUND

This section is intended to introduce various aspects of the art, which may be associated with exemplary embodiments of the present disclosure. This discussion is believed to assist in providing a framework to facilitate a better understanding of particular aspects of the present disclosure. Accordingly, it should be understood that this section should be read in this light, and not necessarily as admissions of prior art.

A petroleum reservoir is generally a subsurface pool of hydrocarbons contained in porous or fractured rock formations. Because a petroleum reservoir typically extends over a large area, possibly several hundred kilometers across, full exploitation entails multiple wells scattered across the area. In addition, there may be exploratory wells probing the edges, pipelines to transport the oil elsewhere, and support facilities. Reservoir structure may directly or indirectly connect fluid channels amongst the multiple wells, and reservoir structure may dictate potential flow rates in the various fluid channels.

Some reservoirs, at some times, may be under sufficient pressure to push hydrocarbons to the surface (e.g., through a wellbore). However, more typically, as the hydrocarbons are produced, the reservoir pressure will decline, and production will falter. Secondary recovery mechanism, and sometimes even tertiary mechanism, may be necessary to improve production. For example, gas, water, or other appropriate injection fluids may be injected into one or more wells to maintain reservoir pressure.

Fluid injection is a widely-used secondary recovery mechanism in traditional reservoir management. The typical objectives of an injection program are reservoir pressure maintenance by voidage replacement and/or production fluid disposal. Fluids may be pumped at high pressure into the reservoir during such operations. Often times, the pressures and/or volumes of fluids to be injected are constrained due to facility limits and/or regulatory limits.

Injection allocation (i.e., distribution of the injection fluid across injection wells and across time) may impact the overall recovery of hydrocarbons from the reservoir.

Traditionally, reservoir simulations are performed at a low frequency, typically semi-annually, and often times even more infrequently. Amongst various other things, this frequency depends on availability of updated reservoir simulation models. Heretofore, it has been assumed that variations that might impact injection allocation targets are relatively stable over time. Similarly, interference tests may be performed from time to time in the field to determine reservoir connectivity. Voidage computations, based on a-priori estimates of injector-producer well pairs, may also be useful in injection allocation planning. However, injection allocation targets are generally updated only infrequently (e.g., once per month or less).

It would be beneficial to provide systems and methods for real-time reservoir management, including, for example, injection surveillance and/or automated injection allocation targets estimation based on physical and/or data-based models of the reservoir and facilities.

### BRIEF DESCRIPTION OF THE DRAWINGS

So that the manner in which the recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates an exemplary field having several wells connected to a subsurface reservoir.

FIG. 2 illustrates components of an exemplary injection surveillance system.

FIG. 3 illustrates a possible view of an exemplary injection surveillance dashboard.

FIG. 4 illustrates components of an exemplary real-time injection management system.

FIG. 5 illustrates a block diagram of an exemplary data analysis system.

### DETAILED DESCRIPTION

It is to be understood that the present disclosure is not limited to particular devices or methods, which may, of course, vary. It is also to be understood that the terminology used herein is for the purpose of describing particular embodiments only, and is not intended to be limiting. As used herein, the singular forms “a,” “an,” and “the” include singular and plural referents unless the content clearly dictates otherwise. Furthermore, the words “can” and “may” are used throughout this application in a permissive sense (i.e., having the potential to, being able to), not in a mandatory sense (i.e., must). The term “include,” and derivations thereof, mean “including, but not limited to.” The term “coupled” means directly or indirectly connected. The word “exemplary” is used herein to mean “serving as an example, instance, or illustration.” Any aspect described herein as “exemplary” is not necessarily to be construed as preferred or advantageous over other aspects. The term “uniform” means substantially equal for each sub-element, within about ±10% variation.

The term “real time” generally refers to the time delay resulting from detecting, sensing, collecting, filtering, amplifying, modulating, processing, and/or transmitting relevant data or attributes from one point (e.g., an event detection/sensing location) to another (e.g., a data monitoring location). In some situations, a time delay from detection of a physical event to observance of the data representing the physical event is insignificant or imperceptible, such that near-real time approximates instantaneous action. Real time may also refer to longer time delays that are still short enough to allow timely use of the data to monitor, control, adjust, or otherwise impact subsequent detections of such physical events.

As used herein, “obtaining” data generally refers to any method or combination of methods of acquiring, collecting, or accessing data, including, for example, directly measuring or sensing a physical property, receiving transmitted data, selecting data from a group of physical sensors, identifying data in a data record, and retrieving data from one or more data libraries.

As used herein, “hydrocarbon management” or “managing hydrocarbons” includes any one or more of the following: hydrocarbon extraction; hydrocarbon production, (e.g., drilling a well and prospecting for, and/or producing, hydrocarbons using the well; and/or, causing a well to be drilled to prospect for hydrocarbons); hydrocarbon exploration; identifying potential hydrocarbon-bearing formations; characterizing hydrocarbon-bearing formations; identifying well locations; determining well injection rates; determining well extraction rates; identifying reservoir connectivity; acquiring, disposing of, and/or abandoning hydrocarbon resources; reviewing prior hydrocarbon management decisions; and any other hydrocarbon-related acts or activities. The aforementioned broadly include not only the acts themselves (e.g., extraction, production, drilling a well, etc.), but also or instead the direction and/or causation of such acts (e.g., causing hydrocarbons to be extracted, causing hydrocarbons to be produced, causing a well to be drilled, causing the prospecting of hydrocarbons, etc.).

As used herein, the “health” of injector facilities and/or wells refers to the extent to which the injector facilities and/or wells are behaving as expected. For example, expected behavior may be based on a mathematical analysis of the physical characteristics of the well, such as rates and/or pressures. At times, “health” may be an assessment of connectivity behavior within a reservoir. At times, an analysis of the physical data of the well in question, such as well level and associated data, may provide a health assessment. If the injector facilities and/or wells are behaving far away from expectation, poor-health may be deemed. At times, the response to a poor health assessment may be corrective action.

If there is any conflict in the usages of a word or term in this specification and one or more patent or other documents that may be incorporated herein by reference, the definitions that are consistent with this specification should be adopted for the purposes of understanding this disclosure.

One of the many potential advantages of the embodiments of the present disclosure is that fluid injection operations may be monitored in real time. Likewise, as the real-time impacts of fluid injection are monitored, injection allocation targets may be updated, and systems may be controlled and/or regulated to improve hydrocarbon recovery. In some cases, critical failures may be avoided with real-time monitoring and fluid injection management. As such, embodiments of the present disclosure may save costs, improve production volumes, and/or reduce risks. Embodiments of the present disclosure can thereby be useful in the discovery and/or extraction of hydrocarbons from subsurface formations.

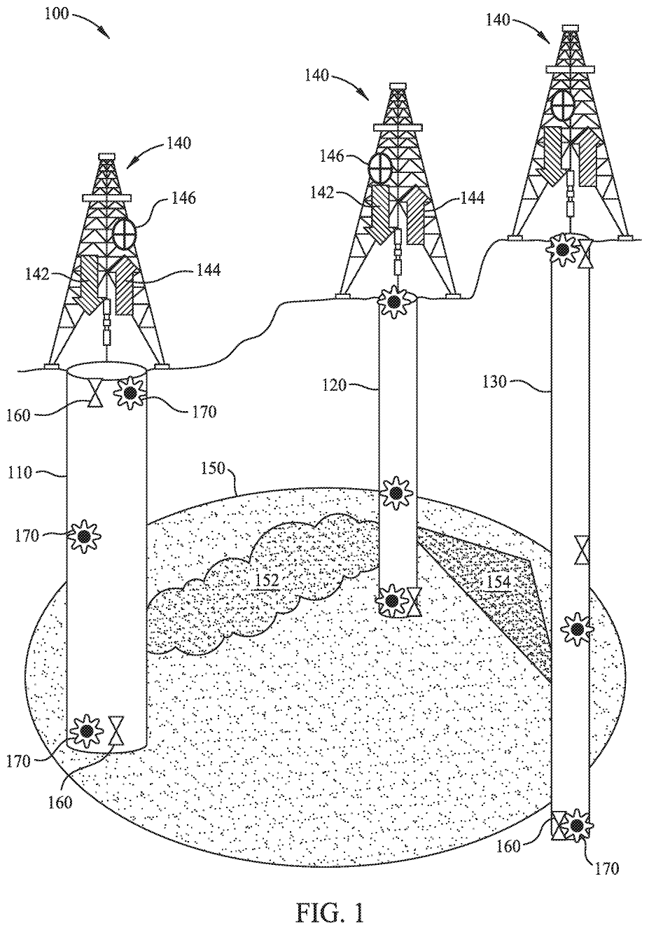

FIG. 1 illustrates an exemplary field 100 having wells 110, 120, 130 connected to subsurface reservoir 150. Various formations and/or structures are thought to exist in reservoir 150, creating fluid channels 152, 154 therein. For example, fluid channel 152 may connect well 110 to well 120, while fluid channel 154 may connect well 120 to well 130. Each of the wells 110, 120, 130 may have pressure sensors 160 and temperature sensors 170 at various locations. For example, well 110 has a pressure sensor 160 and a temperature sensor 170 located at the bottom of the wellbore and at the surface (top) of the wellbore. Well 110 also has a temperature sensor 170 located at a point between the bottom and the top of the wellbore. As illustrated, well 120 has temperature sensors 170 at the bottom, top, and at a midpoint, and a pressure sensor 160 at the bottom. As illustrated, well 130 has temperature sensors 170 at the bottom, top, and at a first midpoint, and pressure sensors 160 at the bottom, top, and a second midpoint. Each of the wells 110, 120, 130 have surface equipment 140 that pumps (injects) fluids into the wells and/or extracts (produces) fluids from the wells. In some embodiments, surface equipment 140 may be subsea. In some embodiments, surface equipment 140 may be shared (e.g., at the earth's surface or subsea) across multiple wells, such as injection manifolds. Injection flow sensors 142 associated with surface equipment 140 may measure the volume, rate, and/or physical characteristics (e.g., viscosity) of fluid injected into wells 110, 120, 130. Production flow sensors 144 associated with surface equipment 140 may measure the volume, rate, and/or physical characteristics (e.g., fluid type) of fluid produced form wells 110, 120, 130. The surface equipment 140 may also have pressure sensors 160 (not shown), temperature sensors 170 (not shown), and/or other types of sensors, such as choke position sensors 146.

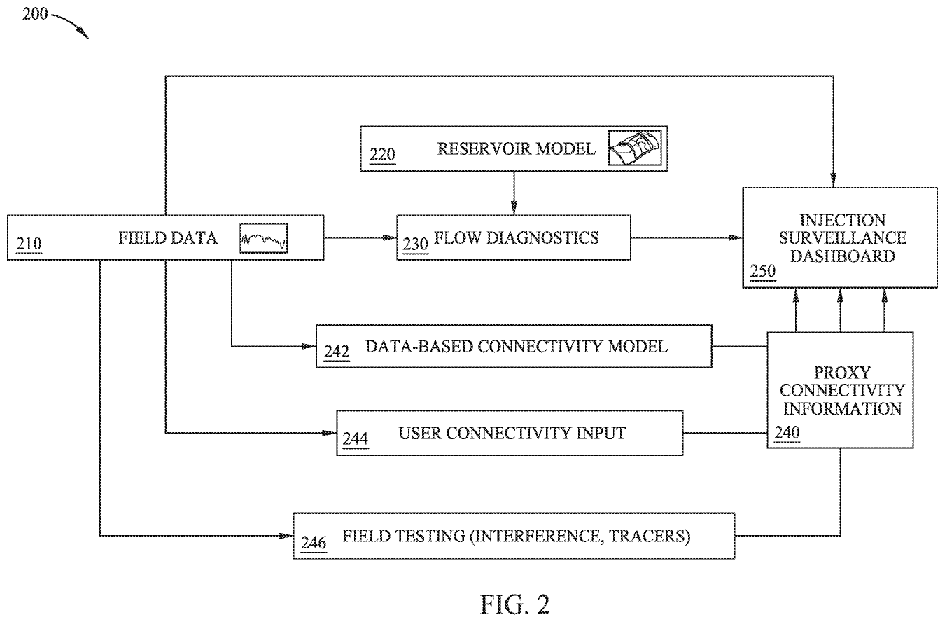

FIG. 2 illustrates components of an exemplary injection surveillance system 200. As part of injection surveillance, field data 210 may be collected regarding field 100, wells 110, 120, 130, surface equipment 140, and/or reservoir 150. For example, field data 210 may include the rates of injected and produced fluids, bottom hole and facilities (e.g., surface equipment) pressures, bottom hole and facilities temperatures, etc. At times (for example when one or more sensors are offline), injection surveillance system 200 may obtain data from a data library, a forecasting system, a simulation, or other data provider in lieu of or in addition to collecting field data 210. Data set completeness may be monitored, for example with an injection surveillance workflow, and injection surveillance system 200 may generate data missing form field data 210 by estimation, interpretation, or interpolation. For example, if field data is available infrequently or has gaps in it, the available data is used to interpolate to estimate the data at the time of interest. As another example, if field data has gaps such that no data is available to interpolate, data in such cases may be interpreted from some physical models or neighboring wells.

As part of injection surveillance, the field data 210 may be used with reservoir model(s) 220 to estimate additional parameters regarding the facilities, the wells, and the reservoir. For example, the reservoir model(s) 220 may be physics-based and/or first-principles model(s) of the reservoir. Such reservoir models may be as simple as a linear pressure curve, or as complex as a full geology model with faults and connectivity representations. The field data 210 may be used with the reservoir model(s) 220 to generate flow diagnostics 230, such as a quantitative estimation of fluid connectivity between wells with multiphase simulations. For example, if reservoir model 220 is a discretized reservoir model, the flow diagnostics 230 may include a single-phase, steady-state flow solution though the reservoir. As another example, flow diagnostics 230 may include a more complicated dynamic multi-phase flow solution to infer fluid connectivity.

In some embodiments, in lieu of or in addition to flow diagnostics 230 from reservoir model(s) 220, proxy connectivity information 240 may be inferred. For example, analysis of field data 210 with a data-based connectivity model 242 may generate proxy connectivity information 240. As another example, field data 210 may be utilized with field testing 246 (such as interference testing and/or injection tracer programs) to generate proxy connectivity information 240. As yet another example, user connectivity input 244 may also be utilized to generate proxy connectivity information 240. In some embodiments, one or more of the data-based connectivity model 242, user connectivity input 244, and field testing 246 may be used together with field data 210 to generate the proxy connectivity information 240.

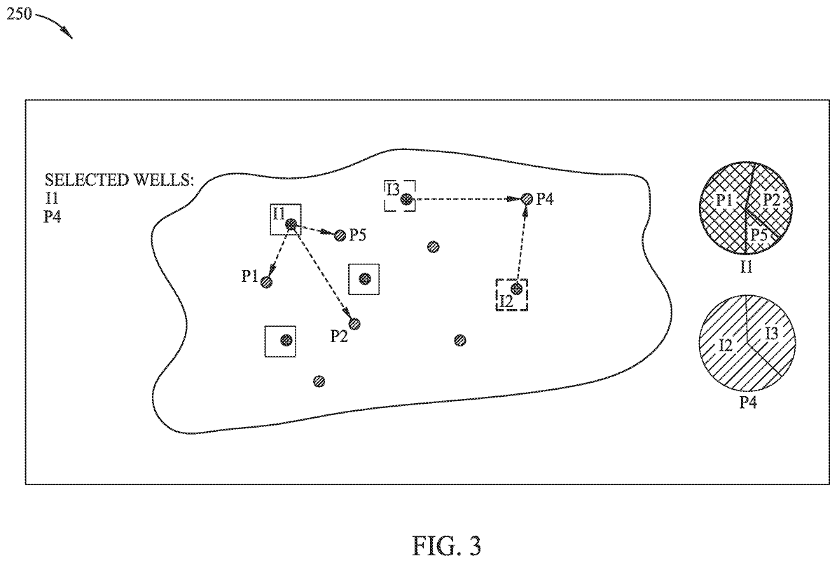

Injection surveillance may include collection of field data 210, updating the reservoir model(s) 220, and/or estimating the additional parameters (e.g., flow diagnostics 230 and/or proxy connectivity information 240) to provide useful results, such as assessment of the health of the injector facilities and/or wells, estimation of the connectivity between different injector-producer well pairs, and/or estimation of the expected time for fluids to travel from a particular injector well to a particular producer well. In some embodiments, any or all of this information may be displayed on an injection surveillance dashboard 250. For example, injection surveillance dashboard 250 may display injector health alerts, connectivity graphs, and/or plots (actual or schematic) of the reservoir. FIG. 3 illustrates a possible view of an injection surveillance dashboard 250, wherein the solid-outline boxes (e.g., around I1) may indicate good injector health, the bold and dashed-outline box (e.g., around I2) may indicate average injector health, while the narrow and dashed-outline box (e.g., around I3) may indicate bad injector health. An estimation of the connectivity between different injector-producer well pairs is indicated on surveillance dashboard 250 by lines between different wells. For example, injector well I1 is connected to producer wells P1, P2 and P5. An extent of connectivity is indicated on surveillance dashboard 250 by pie-charts. For example, the pie chart for injector well I1 illustrates a larger pie piece for producer well P1 than for either producer wells P2 or P5, indicating that the I1-P1 well pair has a stronger relative connection than well pairs I1-P2 or I1-P5.

In some embodiments, injection surveillance system 200 may be operated on an ongoing basis. For example, an automated process may cause the field data 210 to be collected and/or the reservoir model(s) 220 to be updated at regular intervals (e.g., hourly, several times per day, daily, etc.). In some embodiments, injection surveillance system 200 may collect field data 210 and/or update reservoir model(s) 220 with a certain frequency during standard operations, and injection surveillance system 200 may collect field data 210 and/or update reservoir model(s) 220 with a higher frequency during exceptional operations. For example, a trigger (e.g., a data threshold indicative of an unplanned occurrence, a sudden drop in the amount of fluids being injected, or a sudden drop in the bottom hole pressure of the injection well) may switch injection surveillance system 200 from standard-monitoring frequency (e.g., hourly, several times per day, daily, etc.) to exception-monitoring frequency (e.g., every second, every minute, every five minutes, every half hour, etc.). In some embodiments, field data 210 may be collected at least once per week during either standard operations or exceptional operations. In some embodiments, a function of injection surveillance system 200 under exceptional operations may be to preserve records (e.g., making back-up copies of existing data, transmitting data to remote locations, creating duplicative data records, and/or storing existing records to avoid overwriting data).

In some embodiments, injection surveillance system 200 may collect field data 210 on an ad hoc basis. For example, an operator may request updated data, and injection surveillance system 200 may collect one or more types of field data 210 in response to the request. As another example, a trigger (e.g., a data threshold indicative of an unplanned occurrence) may cause injection surveillance system 200 may collect one or more types of field data 210.

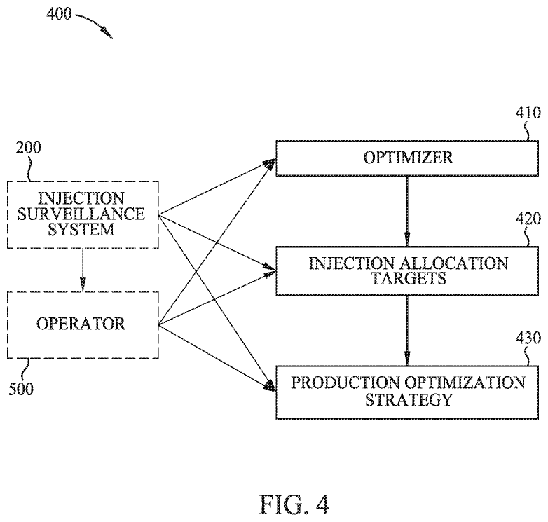

In some embodiments, information (e.g., field data 210, injection allocations, etc.) from the injection surveillance system 200 may be utilized to manage and/or regulate fluid injection for the reservoir. In some embodiments, information from injection surveillance system 200 may be provided to a real-time injection management system. For example, FIG. 4 illustrates components of an exemplary real-time injection management system 400. As illustrated, information from the injection surveillance system 200 may be read, analyzed, monitored, or reviewed by an operator 500 (e.g., through the injection surveillance dashboard 250), thereby influencing and/or informing user input to the injection management system 400 from the operator 500. The real-time injection management system 400 may utilize information from the injection surveillance system 200 and/or the operator 500, for example, to set-up and/or solve a mathematical optimization problem with optimizer 410 representative of field 100, wells 110, 120, 130, surface equipment 140, and/or reservoir 150. In some embodiments, a representation of the optimization problem and/or the solution thereof may be displayed (e.g., overlaid) on injection surveillance dashboard 250.

In some embodiments, injection management system 400 may determine injection allocation targets 420 that optimize certain identified objectives. For example, an identified objective may be to inject a set percentage (e.g., 100%, 80%, 70%, etc., as deemed appropriate by the reservoir engineer) of volume of fluid that is produced (i.e., voidage replacement). As another example, an identified objective may be to inject 80% of volume of fluid that is produced. As another example, an identified objective may be to maintain reservoir pressures above specified thresholds. As another example, an identified objective may be to minimize the rate at which water is produced from any or all of the wells.

Optimizer 410 may be configured to solve an optimization problem to determine injection allocation targets 420. The injection allocation targets 420 may inform or improve the design of a production optimization strategy 430. For example, the optimization problem may have an objective to replace a set percentage of voidage between each injector-producer well pair. The optimization problem may seek to minimize the difference between current and targeted injection allocation for each well to achieve the objective. The optimization problem may seek to minimize the aggregate difference between current and targeted injection allocation over all of the wells connected to a reservoir. In some embodiments, the optimization problem may seek to minimize a value of a function that is based on either the difference between current and targeted injection allocation for each well, or the aggregate difference between current and targeted injection allocation over all of the wells connected to the reservoir (e.g., difference squared, or similar). The optimization problem may be constrained, for example with facility, reservoir, equipment, formation, and/or regulatory constraints. The optimization problem may also include other constraints, such as a well ordering (seriatim) indicative of the optimal injection priority.

In one example, the optimization problem may be expressed as:

Min Σ_{i∈injectors}wᵢ(qᵢ−q*ᵢ)²Σ+_{i∈injectors}kᵢ(qᵢ−qᵢ^{current})² (1)

where, qᵢ is the target injection allocation rate for each injector well that is being computed, q*ᵢ is the injection allocation target rate without any constraints, wᵢ is the weighting depending on relative travel times between different injector-producer well pairs, kᵢ is the regularization weight to penalize significant departure from the current injection allocation rates qᵢ^{current} (typically set to zero). This mathematical optimization problem may be solved using classical optimization techniques to infer injection allocation targets 420 (e.g., injection allocation rate over time for each injector well). Production optimization strategy 430 can be designed by running a reservoir simulation and comparing it to the injection allocation targets 420. In some embodiments, a well-connectivity analysis may set wᵢ and/or q*ᵢ. For example, if a reservoir model is available, an automated well-connectivity analysis may be used to set wᵢ and/or q*ᵢ.

In some embodiments, the weighting wᵢ may be set to the expected “breakthrough time” (i.e., the estimated time for a fluid to travel from an injector well to an offset producer well). By using breakthrough time as a weighting, the objective function may be more influenced by well pairs with longer breakthrough times than well pairs with shorter breakthrough times. Such an objective function may minimize injection fluid cycling. The weighting wᵢ can be directly used or transformed using some mathematical operator, such as a log or square-root, and is generally re-computed every-time the workflow is executed. For each injector well, either the shortest travel time or a weighted average among all the connected producer wells may be chosen.

In some embodiments, the unconstrained injection allocation target rate q*ᵢ may be set to the cumulative voidage volume for each injector well. For example, the cumulative voidage volume may be estimated using injection rates and/or production rates (from field data 210) and connectivity information (from data-based connectivity model 242). In some embodiments, the unconstrained injection allocation target rate q*ᵢ may be set to the instantaneous voidage volumes. The total injection allocation target rate qᵢ (irrespective of any constraint) may be determined for each injector well (based on, for example, the time-horizon on which the voided volume is to be replaced, and/or on the desired replacement ratio).

FIG. 3 illustrates an injection surveillance dashboard 250 that elucidates injection allocation target rate calculations. As illustrated, three injector wells are identified: I1, I2, and I3. As illustrated, four producer wells are identified: P1, P2, P4, P5. As illustrated, injector well I1 is connected to producer wells P1, P2, and P5. As illustrated, Injector wells I2 and I3 are each connected to producer well P4. For the illustrated scenario, 30% of produced fluids from P1 come from I1, 90% of produced fluids from P2 come from I1, and 50% of produced fluids from P5 come from I1. In this scenario, the voided volume at for I1 may be represented as follows:

voidedᵥₒₗᵤₘₑ=0.3Qₚ₁+0.9Qₚ₂+0.5Qₚ₅−Q_{I1} (2)

where Q represents cumulative production and injection volumes at reservoir conditions. The unconstrained injection allocation target rate q*ᵢ for that injector well I1 may then be represented as follows:

$${q}_{1}^{*} = \frac{v r {r}_{target} \times {voided}_{volume}}{v r {r}_{horizon}} \qquad ( 3 )$$

where vrr represents the voidage replacement ratio. Injection allocation target rate calculations may be likewise repeated for each of the injector wells.

In some embodiments, the above-described injection surveillance system 200 and injection management system 400 can be used separately or together. In some embodiments, the above-described injection surveillance system 200 and/or injection management system 400 can be used for a field having a single reservoir with multiple wells or for a field having multiple reservoirs (with multiple wells) sharing common production facilities. In some embodiments, methods and systems described herein may be coupled with other production optimization workflows (such as gas-lift optimization, choke optimization, and routing optimization) in a system-wide production optimization workflow.

The above-described techniques, and/or systems implementing such techniques, can further include hydrocarbon management based at least in part upon models, data, and/or results described herein. For instance, methods according to various embodiments may include managing hydrocarbons based, at least in part, upon wellbore construction and/or operations according to the above-described methods. Moreover, managing hydrocarbons may be based on techniques and systems described herein in conjunction with established production optimization methods, such as gas lift optimization, choke optimization etc.

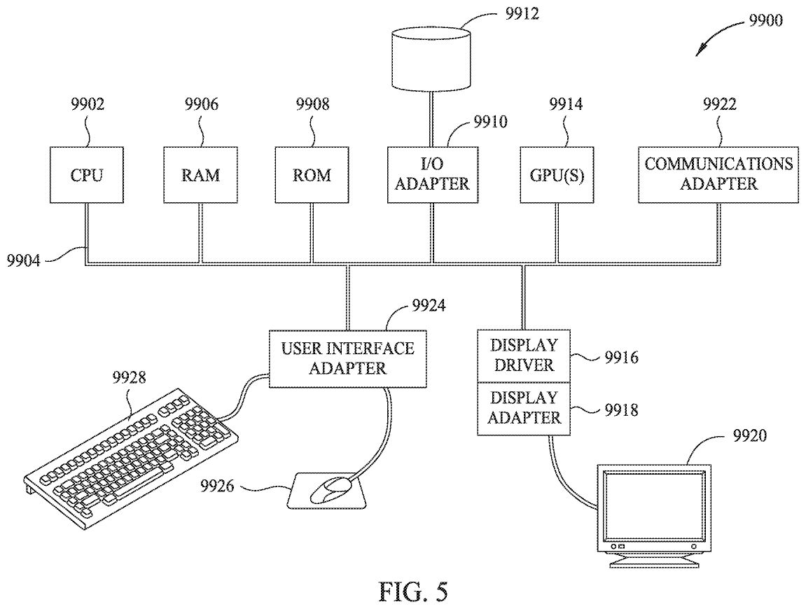

FIG. 5 illustrates a block diagram of a data analysis system 9900 upon which the present technological advancement may be embodied. A central processing unit (CPU) 9902 is coupled to system bus 9904. The CPU 9902 may be any general-purpose CPU, although other types of architectures of CPU 9902 (or other components of exemplary system 9900) may be used as long as CPU 9902 (and other components of system 9900) supports the operations as described herein. Those of ordinary skill in the art will appreciate that, while only a single CPU 9902 is shown in FIG. 5, additional CPUs may be present. Moreover, the system 9900 may comprise a networked, multi-processor computer system that may include a hybrid parallel CPU/GPU system. The CPU 9902 may execute the various logical instructions according to various teachings disclosed herein. For example, the CPU 9902 may execute machine-level instructions for performing processing according to the operational flow described.

The data analysis system 9900 may also include computer components such as non-transitory, computer-readable media. Examples of computer-readable media include a random access memory (“RAM”) 9906, which may be SRAM, DRAM, SDRAM, or the like. The system 9900 may also include additional non-transitory, computer -readable media such as a read-only memory (“ROM”) 9908, which may be PROM, EPROM, EEPROM, or the like. RAM 9906 and ROM 9908 hold user and system data and programs, as is known in the art. The system 9900 may also include an input/output (I/O) adapter 9910, a communications adapter 9922, a user interface adapter 9924, and a display adapter 9918; it may potentially also include one or more graphics processor units (GPUs) 9914, and one or more display driver(s) 9916.

The I/O adapter 9910 may connect additional non-transitory, computer-readable media such as a storage device(s) 9912, including, for example, a hard drive, a compact disc (“CD”) drive, a floppy disk drive, a tape drive, and the like to data analysis system 9900. The storage device(s) may be used when RAM 9906 is insufficient for the memory requirements associated with storing data for operations of the present techniques. The data storage of the system 9900 may be used for storing information and/or other data used or generated as disclosed herein. For example, storage device(s) 9912 may be used to store configuration information or additional plug-ins in accordance with the present techniques. Further, user interface adapter 9924 couples user input devices, such as a keyboard 9928, a pointing device 9926 and/or output devices to the system 9900. The display adapter 9918 is driven by the CPU 9902 to control the display on a display device 9920 to, for example, present information to the user. For instance, the display device may be configured to display visual or graphical representations of any or all of the data and/or models discussed herein.

The architecture of data analysis system 9900 may be varied as desired. For example, any suitable processor-based device may be used, including without limitation personal computers, laptop computers, computer workstations, and multi-processor servers. Moreover, the present technological advancement may be implemented on application specific integrated circuits (“ASICs”) or very large scale integrated (“VLSI”) circuits. In fact, persons of ordinary skill in the art may use any number of suitable hardware structures capable of executing logical operations according to the present technological advancement. The term “processing circuit” encompasses a hardware processor (such as those found in the hardware devices noted above), ASICs, and VLSI circuits. Input data to the system 9900 may include various plug-ins and library files. Input data may additionally include configuration information.

The above-described techniques, and/or systems implementing such techniques, can further include hydrocarbon management based at least in part upon the above techniques. For instance, methods according to various embodiments may include managing hydrocarbons based at least in part upon injection allocation targets constructed according to the above-described methods. In particular, such methods may include operating a well, and/or causing a well to be operated, based at least in part upon the injection allocation targets, optionally be informed by other inputs, data, and/or analyses, as well, and further prospecting for and/or producing hydrocarbons using the well.

The foregoing description is directed to particular example embodiments of the present technological advancement. It will be apparent, however, to one skilled in the art, that many modifications and variations to the embodiments described herein are possible. All such modifications and variations are intended to be within the scope of the present disclosure, as defined in the appended claims.

1. A method of monitoring a field, comprising:
obtaining field data for an injector well coupled to a reservoir;
obtaining a model comprising representations of at least one of the well and the reservoir;
updating the model with the field data for the injector well; and
assessing a status of the injector well based on the field data and the model.

2. The method of claim 1, further comprising displaying the status of the injector well on a dashboard.

3. The method of claim 2, further comprising providing real-time injection surveillance for the field with the dashboard.

4. The method of claim 1, wherein the obtaining field data is repeated at least once every hour.

5. The method of claim 4, wherein assessing the status of the injector well is repeated at least once every hour.

6. The method of claim 1, further comprising:
obtaining field data for a producer well coupled to the reservoir;
updating the model with the field data for the producer well; and
estimating a fluid connectivity between the injector well and the producer well.

7. The method of claim 1, wherein the field comprises a plurality of reservoirs.

8. The method of claim 1, wherein a plurality of injector wells and a plurality of producer wells are coupled to the reservoir.

9. The method of claim 8, further comprising:
obtaining field data for each of the injector wells;
obtaining field data for each of the producer wells;
updating the model with the field data for each of the injector wells and the field data for each of the producer well; and
estimating a fluid connectivity between pairs of wells, each pair comprising one of the injector wells and one of the producer wells.

10. The method of claim 9, wherein estimating the fluid connectivity comprises at least one of:
running single-phase, steady-state flow diagnostics using the field data for each of the injector wells, the field data for each of the producer wells, and the reservoir model;
mining the field data for each of the injector wells and the field data for each of the producer wells to infer reservoir connectivity;
running field tracer programs to infer reservoir connectivity;
conducting interference testing; and
running multiphase reservoir simulations.

11. The method of claim 1, wherein the field data comprises at least one of:
downhole temperature measurements for the injector well;
downhole pressure measurements for the injector well;
injection rate data from surface equipment of the injector well;
choke position from the surface equipment of the injector well;
interpreted data; and
interpolated data.

12. The method of claim 1, wherein the status comprises an injector health assessment.

13. The method of claim 1, further comprising generating flow diagnostics from the field data and the reservoir model.

14. The method of claim 1, further comprising generating proxy connectivity information from the field data and at least one of:
a data-based connectivity model;
field testing; and
user input.

15. The method of claim 1, further comprising providing input to an injection management system.

16. A method of reservoir management comprising:
solving an optimization problem based on unconstrained injection allocation target rates for one or more injector wells and weightings dependent upon relative travel times between injector-producer well pairs, each injector-producer well pairs comprising one of the injector wells;
determining injection allocation targets based on the solution of the optimization problem;
designing a production optimization strategy based on the injection allocation targets.

17. The method of claim 16, further comprising receiving input from an injection surveillance system.

18. The method of claim 16, wherein the weightings are set to expected breakthrough times.

19. The method of claim 16, wherein, for each of the injector wells, the unconstrained injection allocation target rate is set to a cumulative voidage volume for the injector well.

20. The method of claim 16, wherein an objective of the optimization problem comprises at least one of:
replacing a set percentage of voidage between each injector-producer well pair;
minimizing a difference between a current injection allocation rate and the injection allocation target rate for each injector well;
minimizing a value of a function of the difference between the current injection allocation rate and the injection allocation target rate for each injector well;
minimizing an aggregate difference between the current injection allocation rate and the injection allocation target rate for all of the injector wells; and
minimizing a value of a function of the aggregate difference between the current injection allocation rate and the injection allocation target rate for all of the injector wells.
